(19) United States
(12) Patent Application Publication
(10) Pub. No.: US 2024/0213506 A1
(43) Pub. Date: Jun. 27, 2024

(54) METHOD AND APPARATUS FOR ENTERING A STANDARD STATE FOR VANADIUM-BASED BATTERIES

(71) Applicant: STANDARD ENERGY INC., Daejeon (KR)

(72) Inventors: Dong Young Lee, Daejeon (KR); Bu Gi Kim, Daejeon (KR)

(73) Assignee: STANDARD ENERGY INC., Daejeon (KR)

(21) Appl. No.: 18/396,631

(22) Filed: Dec. 26, 2023

(30) Foreign Application Priority Data
Dec. 27, 2022 (KR) 10-2022-0185854

(51) Int. Cl. H01M 8/04992; G01R 31/3835; H01M 8/04537; H01M 8/04746; H01M 8/18

(52) U.S. Cl. CPC H01M 8/04992; G01R 31/3835; H01M 8/04559; H01M 8/04753; H01M 8/188

(57) ABSTRACT

At least some embodiments herein are related to a semiconductor chip assembly comprising: a memory containing information related to entering a standard state for a vanadium-based battery; and a processor, operatively connected with the memory, that provides instructions or commands related to entering the standard state for the vanadium-based battery, by setting a constant temperature that is used in performing open circuit voltage (OCV) measurements, by setting one or more voltage values with respect to a particular voltage region that is used in performing the OCV measurements, and maintaining an equilibrium state of the vanadium-based battery while performing the OCV measurements. Also disclosed is a method comprising: entering a standard state for a vanadium-based battery and maintaining an equilibrium state of the vanadium-based battery while performing the OCV measurements. Additionally disclosed is a system comprising: at least one energy storage component having a plurality of vanadium-based batteries arranged in cells or packs; and a battery management component, operatively connected with the energy storage component, to provide battery management control for entering a standard state for the energy storage component.

### CROSS-REFERENCE TO RELATED APPLICATION(S)

This application claims priority benefit to Korean Patent Application No. 10-2022-0185854 filed on Dec. 27, 2022, which is hereby incorporated by reference in its entirety.

### BACKGROUND

The disclosed technology relates to battery technologies, and more particularly, to a method and apparatus for entering a standard state for vanadium-based batteries.

The global economic growth accompanied by global warming continues increase the urgency of a need for renewable and sustainable energy systems based on renewable energy, e.g., solar and wind energy. To enhance the stability of grid networks against fluctuations due to intermittent availability such forms of energy, advances in energy storage system (ESS) technology are used for storing surplus electricity, which can be delivered to end customers or to power grids when needed. It should be noted that an ESS can also be referred to an electrical energy storage system (EES). Among others, an ESS based on electrochemical energy, e.g., rechargeable or secondary batteries, can provide cost effective and clean forms of energy storage solutions. Examples of electrochemical energy storage systems include lithium-ion, lead-acid, sodium-sulfur and redox-flow batteries. Different storage times are needed for different applications: short-term storage, medium-term storage, and long-term storage. The different types of electrochemical energy storage systems have different physical and/or chemical properties. Competing factors that are weighed in the selection and design of a suitable electrochemical energy storage system for a particular application includes investment cost, power, energy, lifetime, recyclability, efficiency, scalability, and maintenance costs, among others.

Among various electrochemical energy storage systems, so-called redox batteries (RBs) are considered to be promising for stationary energy storage. RBs are electrochemical energy conversion devices, that exploit redox processes of redox species dissolved in a solution. Advantageous features of the RBs include relative safety, independent scalability of power and energy, high depth of discharge (DoD), and reduced environmental impact. Such features allow for wide ranges of operational powers and discharge times, making RBs desirable for storage of electricity generated from renewable sources.

### SUMMARY

This summary introduces a selection of concepts in simplified form that are described in the present disclosure. This summary neither identifies features as key or essential, nor limits the scope, of the claimed subject matter.

For enhancements related to existing electrochemical energy storage systems, the inventors of the present disclosure have performed research and development, in particular, for finding improvements and solutions with respect to implementing lithium-ion batteries into an energy storage system (ESS), which continue to encounter certain dangerous factors, such as fire hazards, occurrence of explosions, and the like.

To solve such issues upon recognition of the above-identified problems, the inventors of the present disclosure have considered specific technical solutions for adapting vanadium-based batteries to be appropriate for energy storage system (ESS) implementation.

Accordingly, one among many aspects of the present disclosure is to provide a method and apparatus used in performing various evaluations for vanadium-based batteries to be employed in energy storage systems (ESS) or other implementations.

Additionally, another among many aspects of the present disclosure is to provide a method and apparatus for performing necessary measurements upon entering a standard state for vanadium-based batteries, the standard state being adapted to and appropriate for the unique electrochemical technical characteristics of vanadium-based batteries, to thus perform evaluations therefor.

In order to address the above issues, this disclosure provides a semiconductor chip assembly comprising: a memory containing information related to entering a standard state for a vanadium-based battery; and a processor operatively connected with the memory, and configured to provide instructions or commands for entering of the standard state for the vanadium-based battery, the standard state entered by setting a constant temperature that is used in performing open circuit voltage (OCV) measurements, and by setting one or more voltage values with respect to a particular voltage region that is used in performing the OCV measurements, the processor is further configured to provide instructions or commands for maintaining an equilibrium state of the vanadium-based battery while performing the OCV measurements.

According to at least one embodiment of the present disclosure, there is provided a method for a semiconductor assembly, the method comprising: entering a standard state for a vanadium-based battery by setting a constant temperature that is used in performing open circuit voltage (OCV) measurements, and by setting a plurality of voltage values with respect to a particular voltage region that is used in performing the OCV measurements; and maintaining an equilibrium state of the vanadium-based battery while performing the OCV measurements.

According to at least one embodiment of the present disclosure, there is provided a system having a semiconductor chip assembly, the system comprising: at least one energy storage component having a plurality of vanadium-based batteries arranged in cells or packs; and a battery management component, operatively connected with the energy storage component, and configured to provide battery management control for entering a standard state for the energy storage component, the standard sate entered by setting a constant temperature that is used in performing open circuit voltage (OCV) measurements for the vanadium-based batteries arranged in cells or packs, and by setting a plurality of voltage values with respect to a particular voltage region that is used in performing the OCV measurements for the vanadium-based batteries arranged in cells or packs, wherein the battery management component is further configured to provide battery management control for maintaining an equilibrium state of the energy storage component or at least one of the vanadium-based batteries therein while performing the OCV measurements.

By setting and employing the standard conditions for vanadium-based batteries according to the embodiments of the present disclosure, more accurate measurements and deductions can be performed on vanadium-based batteries, when compared to the situation where such standard conditions are not set and not employed.

Also, by employing the standard conditions for vanadium-based batteries according to the embodiments of the present disclosure, the charging and/or discharging of vanadium-based batteries can be more effectively performed, which allows for more accurate battery management, power control and energy storage system operations.

In particular, the embodiments of the present disclosure allow for vanadium-based batteries to be appropriately adapted for and implemented into an energy storage system (ESS).

The following description references the accompanying drawings which form a part this application, and which show, by way of illustration, specific example implementations. Other implementations may be made without departing from the scope of the disclosure.

### BRIEF DESCRIPTION OF THE DRAWINGS

FIG. 1 shows an exemplary redox battery cell that can be implemented as part of a vanadium-based battery and/or energy storage systems applicable to at least some embodiments described herein.

FIG. 2 shows a perspective view of an exemplary structure of a vanadium-based battery applicable to at least some embodiments described herein.

FIG. 3 shows a cross-sectional view along the dotted line A-A of FIG. 2.

FIG. 4 shows an exemplary battery module having a plurality of vanadium-based battery cells applicable to at least some embodiments described herein.

FIG. 5 shows some characteristics of a constant current (CC) control method and/or a constant voltage (CV) control method being applied to battery charging applicable to at least some embodiments described herein.

FIG. 6 shows the relationship of the voltage and current during charging and discharging at the two electrodes of VFRB applicable to at least some embodiments described herein.

FIG. 7 shows some graphs for different data sets with data regarding the charging and discharging of a battery at constant current.

FIG. 8 shows some basic electrochemical characteristics of a vanadium-based battery according to at least some embodiments described herein.

FIG. 9 shows two situations for battery cell resistance versus IR drops at or near the inflection points during charging or discharging according to at least some embodiments described herein.

FIG. 10 shows some exemplary graphs for experimental results that depict the determination of termination discharge voltage at high current density using pulsed galvanostatic measurement curves and internal resistance curves applicable to at least some embodiments described herein.

FIG. 11 depicts the SoC versus OCV relationships for short charging time, for long charging/discharging time, and for short discharging time.

FIG. 12 depicts the effects of environmental temperature on vanadium-based battery performance.

FIG. 13 shows an exemplary flow chart of the procedures for entering a standard state for a vanadium-based battery according to at least some embodiments described herein.

FIG. 14 shows an exemplary apparatus that can perform the steps of FIG. 13 according to at least some embodiments described herein.

FIG. 15 shows a semiconductor chip assembly according to at least some embodiments described herein.

### DETAILED DESCRIPTION

Various changes to the following embodiments are possible and the scope of the present disclosure is not limited to the following embodiments.

Unless otherwise defined, all terms including technical and scientific terms used herein have the same meaning as commonly understood by one of ordinary skill in the art to which the present disclosure belongs. In the following description, it is to be noted that, when the functions of conventional elements and the detailed description of elements related with the present disclosure may make the gist of the present disclosure unclear, a detailed description of those elements will be omitted.

In addition, below drawings are provided by way of example so that the idea of the present disclosure can be sufficiently transferred to those skilled in the art to which the present disclosure pertains. Therefore, the present disclosure is not limited to the accompanying drawings provided below but may be modified in many different forms. In addition, the accompanying drawings suggested below may be exaggerated in order to make clear the spirit and scope of the present disclosure. Furthermore, like reference numerals denote elements throughout the specification.

The terminology used herein is for the purpose of describing particular embodiments only and is not intended to be limiting. As used herein, the singular forms “a”, “an”, and “the” are intended to include the plural forms as well, unless the context clearly indicates otherwise.

Further, when describing the components of the present disclosure, terms such as first, second, A, B, (a) or (b) may be used. Since these terms are provided merely for the purpose of distinguishing the components from each other, they do not limit the nature, sequence, or order of the components. It will be understood that when an element is referred to as being “coupled” or “connected” to another element, it can be directly coupled or connected to the other element or intervening elements may be present therebetween.

In the present disclosure, the term “battery cell” is a minimum unit in which charging, and discharging occur through electrolyte, and includes a membrane, separator, etc. in which ion exchange occurs.

In the present disclosure, the term “stack” means that a plurality of battery cells are stacked or configured.

Vanadium-based batteries, such as, so-called vanadium redox batteries (VRBs), vanadium redox/flow batteries (VRFBs or VFRBs), vanadium flow batteries (VFBs), vanadium ion batteries (VIBs), and the like are considered to be even more promising for ESS/EES implementation and other applications related to the battery industry. Such vanadium-based batteries have at least some of the same advantages that are characteristic of RFBs. However, unlike conventional non-vanadium-based RFBs, vanadium-based batteries are significantly less flammable and less prone to damage due to the characteristics of the vanadium implemented therein.

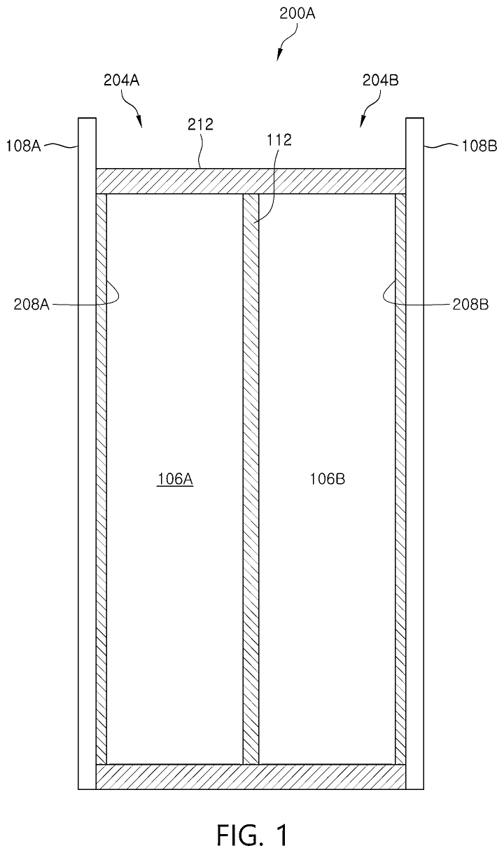

Referring to FIG. 1, a notable structural distinction of the redox battery according to some embodiments herein, relative to some conventional redox batteries such as redox flow batteries (RFBs) is the omission of pumps. Instead, the redox battery 200A according to some embodiments are configured such that the first and second electrolytes self-circulate within respective ones of the positive electrolyte reservoir 106A of the first half cell 204A and the negative electrolyte reservoir 106B of the second half cell 204B. In various configurations, self-circulation of the first and second electrolytes is caused by one or more of: an osmotic pressure difference between the first and second electrolyte reservoirs; a density change in one or both of the first and second electrolytes; diffusion or migration of one or both of the first and second electrolytes; an affinity of one or both of the first and second electrolytes toward a respective ones of the first and second electrodes; the first and second redox half reactions; and thermal expansion or contraction of one or both of the first and second electrolytes. The inventors have discovered that self-circulation is effective to provide stability of the power and energy output when the thicknesses of the positive and negative electrolyte reservoirs 106A, 106B in their cross-sections do not exceed 20 cm, 15 cm, 10 cm, 5 cm, 2 cm, 1 cm or a value in a range defined by any of these values.

Thus configured, the redox battery provides various technical and commercial advantages. For example, various reliability failures associated with the conduits, e.g., pipe joints, between the battery cell and the tanks, as well as pumps for circulating the electrolytes, are substantially reduced or eliminated, which in turn reduces unscheduled repairs as well as safety hazard and operational cost associated with operation of the redox battery 200A. In addition, extrinsic efficiency is substantially improved by obviating a need to circulate the electrolyte between the battery cell and the tanks using pumps. The inventors have realized that depending on the size of the system, the redox battery 200A can improve the power or energy density by up to 2-50 times compared to conventional RFBs by obviating a need to circulate the electrolyte between the cell and the electrolyte tanks. As described above, a power or energy density refers to the power or energy output of a storage device relative to the total volume of the energy storage device, respectively. Thus, for a redox battery, the power or energy density refers to a ratio of the power or energy output to the total volume of the redox battery, respectively. In addition, the space efficiency is greatly improved by the omission of a circulation system including separate tanks, pumps and conduits. Furthermore, the system complexity is greatly reduced, thereby greatly reducing the barrier to commercial implementation of the redox battery. For example, unlike conventional RFBs, the redox battery 200A can be manufactured in packs similar to lithium-ion batteries for modularized implementation, rendering them more adapted for automation and mass production, without a need for intrusive construction that may be needed for installing conventional RFBs.

In the following, the operating principle and aspects of the redox battery are described using an example of a vanadium (V) redox battery, which is based on vanadium-based redox pairs. However, it will be understood that embodiments are not so limited, and the principles described herein can be applied to redox batteries according to various other redox pairs.

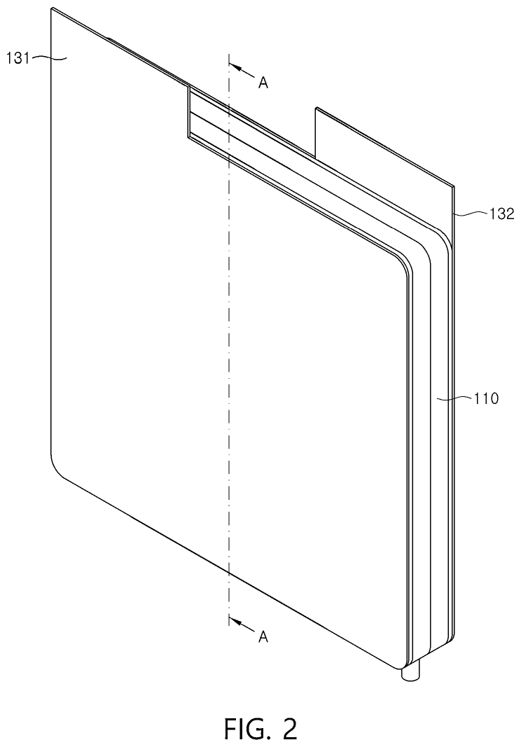

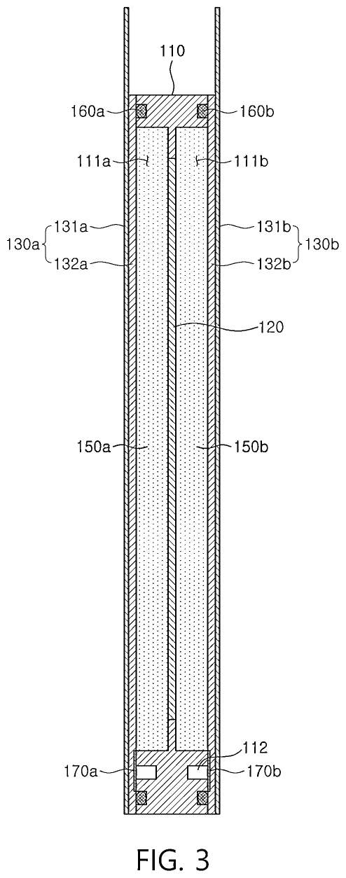

Reference to FIGS. 2 through 6 will be made hereafter.

An exemplary structure of a vanadium-based battery (such as a vanadium ion battery: VIB) applicable to at least some embodiments described herein is comprised of a so-called first liquid electrode at which a first electrochemical reaction takes place, a so-called second liquid electrode at which a second electrochemical reaction takes place, a frame (110) having a first electrode receptacle/reservoir (111a) that accommodates the first liquid electrode and having a second electrode receptacle/reservoir (111b) that accommodates the second liquid electrode, and a separation/ion exchange membrane (120) between the first electrode receptacle (111a) and the second electrode receptacle (111b). Also, there is a first current collector (130a) in contact with the first electrode receptacle (111a) and in electrical connection with the first liquid electrode, and a second current collector (130b) in contact with the second electrode receptacle (111b) and in electrical connection with the second liquid electrode. Additionally, there can be a first solid electrode (bipolar plate) (150a) at the first electrode receptacle (111a) impregnated in the first liquid electrode, and a second solid electrode (bipolar plate) (150b) at the second electrode receptacle (111b) impregnated in the second liquid electrode. Furthermore, there is a first insulator (170a) between the frame (110) and the first current collector (130a) and a second insulator (170b) between the frame (110) and the second current collector (130b).

The so-called liquid electrodes contain certain ions that undergo redox (i.e., reduction and oxidation) reactions. As such, the first liquid electrode can be an electrolyte having a dissolution of anode redox couples therein. Although an anode redox couple can be implemented as an element or component containing transition metals such as titanium (Ti), vanadium (V), chrome (Cr), manganese (Mn), iron (Fc), cobalt (Co) or zinc (Zn), bromine (Br) and cesium (Cs). At least some of the embodiments herein employ vanadium (V) to thus form V²⁺/V³⁺ redox couples. The first liquid electrode can be an acidic aqueous solution, such as sulfuric acid (H₂SO₄), that can induce or allows for transmission of electrical currents upon ionization occurring therein. In some embodiments, the first liquid electrode can be manufactured by dissolution of VOSO₄ (vanadylsulfate), V₂O₅ (vanadium pentoxide) or some other appropriate material into a H₂SO₄ (sulfuric acid) solution.

The first liquid electrode undergoes a so-called first half cell reaction shown below, whereby the right-pointing arrow (→) indicates a discharge direction and the left-pointing arrow (←) indicates a charging direction: V²⁺←→V³⁺+e⁻

Namely, during discharging, vanadium ions having an oxidation state of +2 (i.e., V²⁺ ions) are oxidized to vanadium ions having an oxidation state of +3 (i.e., V³⁺ ions), and during charging, vanadium ions having an oxidation state of +3 (i.e., V³⁺ ions) are reduced to vanadium ions having an oxidation state of +2 (i.e., V²⁺ ions).

The frame (110), the first collector (130a) and the separation membrane (120) surround the first liquid electrode accommodated in the first electrode receptacle (111a), which is configured to prevent (or minimize) any leakage of the first liquid electrode, and the first solid electrode (150a) may be immersed into the first liquid electrode.

As the first liquid electrode is electrically connected with the first current collector (130a), electrons move toward the first current collector (130a) during discharging and electrons move away from the first current collector (130a) during charging. Also, because the first liquid electrode is in contact with the separation membrane (120), hydrogen cations (i.e., positive ions or protons) can move or pass through the separation membrane (120).

In a similar manner, the second liquid electrode can be an electrolyte having a dissolution of anode redox couples therein. Although an anode redox couple can be implemented as an element or component containing transition metals such as titanium (Ti), vanadium (V), chrome (Cr), manganese (Mn), iron (Fe), cobalt (Co) or zinc (Zn), bromine (Br) and cesium (Cs). At least some of the embodiments herein employ vanadium (V) to thus form V⁴⁺/V⁵⁺ redox couples. The second liquid electrode can be an acidic aqueous solution, such as sulfuric acid (H₂SO₄), that can induce or allows for transmission of electrical currents upon ionization occurring therein. In some embodiments, the second liquid electrode can be manufactured by dissolution of VOSO₄ (vanadylsulfate), V₂O₅ (vanadium pentoxide) or some other appropriate material into a H₂SO₄ (sulfuric acid) solution.

The second liquid electrode undergoes a so-called second half cell reaction shown below, whereby the right-pointing arrow (→) indicates a discharge direction and the left-pointing arrow (←) indicates a charging direction: V⁵⁺+e⁻←→V⁴⁺

Namely, during discharging, vanadium ions having an oxidation state of +5 (i.e., V⁵⁺ ions) are oxidized to vanadium ions having an oxidation state of +4 (i.e., V⁴⁺ ions), and during charging, vanadium ions having an oxidation state of +4 (i.e., V⁴⁺ ions) are reduced to vanadium ions having an oxidation state of +5 (i.e., V⁵⁺ ions).

The frame (110), the second collector (130b) and the separation membrane (120) surround the second liquid electrode accommodated in the second electrode receptacle (111b), which is configured to prevent (or minimize) any leakage of the second liquid electrode, and the second solid electrode (150b) may be immersed into the second liquid electrode.

As the second liquid electrode is electrically connected with the second current collector (130b), electrons move toward the second current collector (130b) during discharging and electrons move away from the second current collector (130b) during charging. Also, because the second liquid electrode is in contact with the separation membrane (120), hydrogen cations (i.e., positive ions or protons) can move or pass through the separation membrane (120).

As can be understood from above, the first and second liquid electrodes can be of the same material or composition, which contains vanadium ions in the same electrolyte. Hereafter, the first and second liquid electrodes will simply be referred to as a liquid electrode.

The frame (110) may have a rectangular loop shape as depicted in the drawings. Some embodiments may employ different shapes, such as a rhombus shape, a circular shape, or a pentagon or other polygonal shape. Also, the frame (110) can have a particular thickness. At least part of the frame (110) can form at least part of the first and second electrode receptacles (111a, 111b). The particular shape and/or thickness of the frame (110) will depend on how the vanadium-based battery is implemented and the structural requirements needed therefor, upon consideration of a trade-off relationship among overall size, weight, battery capacity, charging/discharging operation, manufacturing costs, and the like.

The space created in or by the frame (110) is divided into the first electrode receptacle (111a) and the second electrode receptacle (111b) due to the separation membrane (120) therebetween, which can be attached to and/or supported by the frame (110).

At one side, one end or one edge of the frame (110), the first current collector (130a) is located, and the second current collector (130b) is located in an opposing manner at another side, end or edge of the frame (110). Furthermore, the space of the frame (110) is closed off by the first current collector (130a) and the second current collector (130b), and thus the entire structure at and around the frame (110) is configured such that the first and second liquid electrodes do not leak therefrom. Thus, the frame (110) forms the first electrode receptacle (111a) between the first current collector (130a) and the separation membrane (120), and forms the second electrode receptacle (111b) between the second current collector (130b) and the separation membrane (120).

It can be said that the first and second liquid electrodes are accommodated in the frame (110) and the first and second solid electrodes (150a, 150b) are positioned respectively therein. Also, first and second gaskets (160a, 160b) may be respectively provided along a first and second periphery or edge of the frame (110). Additionally, a first insulation member (170a) is at one side of the frame (110) and a second insulation member (170b) is at an opposing side thereof.

The first electrode receptacle (111a) and the second electrode receptacle (111b) are in fluid communication with each other via a transition element (112) that is part of the frame (110). Such transition element (112) can be part of the frame (110), in the form of a groove or channel at or along an edge thereof and having a hole or opening at each end thereof. The liquid electrode may flow enter such holes or openings and flow through the groove or channel of the frame (110).

The separation membrane (120) is within the frame (110) to separate the first and second liquid electrodes and allows for hydrogen cations (i.e., positive ions or protons) to move or pass therebetween. The separation membrane (120) is between the first and second current collectors (130a, 130b) and is attached to an edge of the frame (110). During discharge, the hydrogen cations move from the first liquid electrode to the second liquid electrode and move from the second liquid electrode to the first liquid electrode during charging.

The separation membrane (120) may include at least one among perfluorinated ionomer, partially fluorinated polymer and non-fluorinated hydrocarbons) and may be made of material from at least one among Nafion®, Flemion®, NEOSEPTA-F® and Gore Select®, or from some other commercially available materials.

The separation membrane (120) basically prevents the first and second liquid electrodes from mixing with each other, but there may be some cross-over effects caused by small amounts of vanadium ions and water that may pass through. Such cross-over effects can cause an unbalance in the respective amounts of the first and second liquid electrodes, which can affect the performance and lifespan of the vanadium-based battery. Some conventional redox secondary battery systems having tanks and pumps may be able to resolve such undesirable differences in the amounts of liquid electrode material, but the embodiments described herein do not employ such tanks and pumps. Instead, the embodiments described herein are specifically configured to allow small amounts of liquid electrode to flow between the first and second electrode receptacles (111a, 111b) in order to resolve any unbalancing due to cross-over to thus maintain a relative equilibrium therebetween.

The first current collector (130a) is provided along one side of the frame (110) and together with the separation membrane (120) form the first electrode receptacles (111a). In a corresponding manner, the second current collector (130b) is provided as counterpart to the first current collector (130a). Also, the first current collector (130a) is in adhering contact with the first gasket (160a) at the frame (110) and in contact with the first insulation member (170a), but not in direct contact with the first and second liquid electrodes that can flow in small amounts through the transition element (112). Additionally, the first current collector (130a) is in electrical contact with the first liquid electrode to allow electrons to move and thus current to flow during charging and discharging.

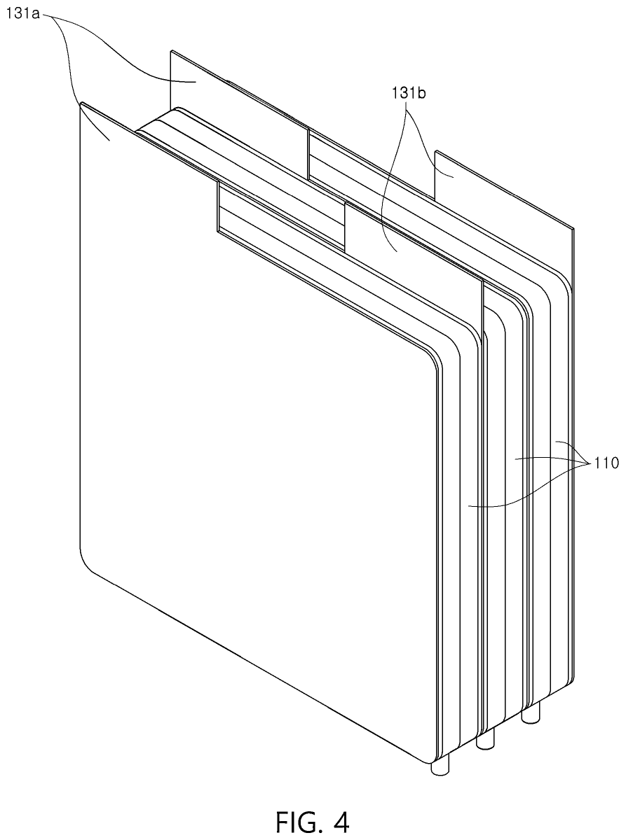

As per FIG. 4, when a plurality batteries or battery cells form a module, whereby a plurality of frames (110) and a plurality of first and second current collectors (130a, 130b) are stacked, at least one among the first and second current collectors (130a, 130b) can be electrically connected via a busbar (not shown) or other connector to achieve parallel connection of the batteries or battery cells.

The first current collector (130a) comprises a first metal current collector (131a) made of metal and electrically connected with the busbar, and a first carbon current collector (132a) between the frame (110) and the first metal current collector (131a).

The first carbon current collector (132a) can be made of graphite, carbon, carbon plastic, and the like, which has high conductivity and high acid-resisting properties. The first carbon current collector (132a) is located between the first liquid electrode and the first metal current collector (131a) such that electrons can move therebetween but causing without oxidation to the first metal current collector (131a). The first carbon current collector (132a) may have a rectangular plate shape or may be applied onto the first metal current collector (131a).

The first metal current collector (131a) is made of a highly conductive material, such as copper or aluminum, and can have a rectangular plate shape with at least a portion thereof protruding therefrom to allow connection with the busbar or connector.

The first metal current collector (131a) can be made of a flexible film or of a rigid plate. As shown in FIG. 4, when a plurality batteries or battery cells form a module, a majority of the first metal current collectors (131a) can be flexible films, with some being a rigid plate which may provide better connection with the busbar or connector.

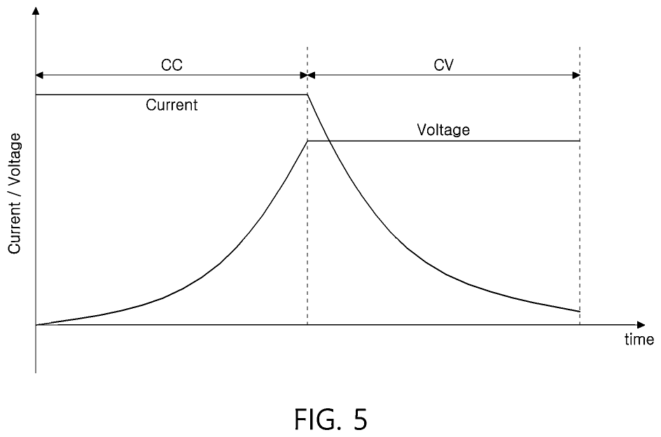

The first carbon current collector (132a) is located at one side of the first metal current collector (131a). As shown in FIG. 5, when a plurality batteries or battery cells form a module, a first carbon current collector (132a) is located at both sides of the first metal current collector (131a).

The second current collector (130b) is located at an opposing side of the frame (110) and together with the separation membrane (120) and the frame (110) form the second electrode receptacle (111b). The second current collector (130b) is parallel to and spaced apart from the first current collector (130a). The second current collector (130b) in adhering contact with the second gasket (160b) at the frame (110) and in contact with the second insulation member (170b), but not in direct contact with the first and second liquid electrodes that can flow in small amounts through the transition element (112). Additionally, the second current collector (130b) is in electrical contact with the first liquid electrode to allow electrons to move and thus current to flow during charging and discharging.

As per FIG. 4, when a plurality batteries or battery cells form a module, whereby a plurality of frames (110) and a plurality of first and second current collectors (130a, 130b) are stacked, at least one among the first and second current collectors (130a, 130b) can be electrically connected via a busbar (not shown) or other connector to achieve parallel connection of the batteries or battery cells.

The second current collector (130b) comprises a second metal current collector (131b) made of metal and electrically connected with the busbar, and a second carbon current collector (132b) between the frame (110) and the second metal current collector (131b).

The second carbon current collector (132b) can be made of graphite, carbon, carbon plastic, and the like, which has high conductivity and high acid-resisting properties. The second carbon current collector (132b) is located between the second liquid electrode and the second metal current collector (131b) such that electrons can move therebetween but causing without oxidation to the second metal current collector (131b). The second carbon current collector (132b) may have a rectangular plate shape or may be applied onto the second metal current collector (131b).

The second metal current collector (131b) is made of a highly conductive material, such as copper or aluminum, and can have a rectangular plate shape with at least a portion thereof protruding therefrom to allow connection with the busbar or connector.

The second metal current collector (131b) can be made of a flexible film or of a rigid plate. As shown in FIG. 4, when a plurality batteries or battery cells form a module, a majority of the second metal current collectors (131b) can be flexible films, with some being a rigid plate which may provide better connection with the busbar or connector.

The second carbon current collector (132b) is located at one side of the second metal current collector (131b). As shown in FIG. 5, when a plurality batteries or battery cells form a module, a second carbon current collector (132b) is located at both sides of the second metal current collector (131b).

According to some embodiments, the first gasket (160a) provides a seal between the first current collector (130a) and the frame (110) and the second gasket (160b) provides a seal between the second current collector (130b) and the frame (110).

The first and second gaskets (160a, 160b) may be of a flexible material, such as rubber or synthetic resin, and can be in the form of a rectangular loop or some other form that matches the shape of the frame (110).

The first solid electrode (150a) is located in the first electrode receptacle (111a) and impregnated into the first liquid electrode. The first solid electrode (150a) has the frame (110), the first current collector (130a) and the separation membrane (120) surrounding thereto. The first solid electrode (150a) can include carbon-based materials, such as carbon or graphite felt, carbon cloth, carbon black, graphite powder or graphene. The first solid electrode (150a) may be in a porous rectangular parallelepiped form. The first solid electrode (150a) can have a thickness that is greater than that of the first electrode receptacle (111a), and in such case, may be accommodated therein in an adhering contact manner. Also, the first solid electrode (150a) is in close contact with the first current collector (130a) and the separation membrane (120).

The second solid electrode (150b) can include carbon-based materials, such as carbon or graphite felt, carbon cloth, carbon black, graphite powder or graphene. The second solid electrode (150b) may be in a porous rectangular parallelepiped form. The second solid electrode (150b) can have a thickness that is greater than that of the second electrode receptacle (111b), and in such case, may be accommodated therein in an adhering contact manner. Also, the second solid electrode (150b) is in close contact with the second current collector (130b) and the separation membrane (120).

For the secondary battery having the above-described structure of the present disclosure, the overall configuration can be explained as follows.

The separation membrane (120) is disposed at a middle of the out-of-plane direction of the frame (110) that has a rectangular shape with a particular thickness, and at one side of the frame (110) in the out-of-plane direction, the first current collector (130a) is disposed, and the second current collector (130b) is disposed on the other side of the frame (110) in the out-of-plane direction, to thus form the first electrode receptacle (111a) and the second electrode receptacle (111b). Namely, the frame (110) is disposed in between the first current collector (130a) and the second current collector (130b), and the separation membrane (120) is disposed within the w frame (110).

Referring to FIG. 4, the above-described structure is alternatingly repeated to form a module. Namely, the first current collector (130a) is disposed between a plurality of frames (110) having attached thereto the separation membrane (120), and the second current collector (130b) can be disposed between a plurality of frames (110) having attached thereto the separation membrane (120).

At the first electrode receptacle (111a), the first solid electrode (150a) having the first liquid electrode impregnated therein is disposed, and at the second electrode receptacle (111b), the second solid electrode (150b) having the second liquid electrode impregnated therein is disposed. A first gasket (160a) is disposed between the first current collector (130a) and the frame, and a second gasket (160b) is disposed between the second current collector (130b) and the frame.

The first current collector (130a) includes a first carbon current collector (132a) and a first metal current collector (131a), and the second current collector (130b) includes a second carbon current collector (132b) and a second metal current collector (131b). At a side of the first electrode receptacle (111a), the first carbon current collector (132a) and the first metal current collector (131a) can be sequentially stacked. At a side of the second electrode receptacle (111b), the second carbon current collector (132b) and the second metal current collector (131b) can be sequentially stacked.

Hereafter, some aspects about the battery charging and discharging operations of secondary or redox (e.g., vanadium-based) batteries will be explained.

Establishing an accurate charge/discharge voltage range for a battery is not an easy task. The voltages in a battery are affected by the constitution of the elements in the battery, the charge/discharge conditions, charge/discharge control methods, and the like. In such an environment having many variables, only two reliable types of measurements (i.e., voltage and current) are practically available.

Typically, companies in the battery-related industry have been basically using trial and error methods in attempts to establish an appropriate charge/discharge voltage range for their products. For most batteries, the two opposing end points in state-of-charge (SoC) characteristics are where extreme changes in voltages (i.e., electromotive force: EMF) are observed. Namely, the slope of the charge/discharge curve changes drastically as a fully charged state or a fully discharged state as being reached. Many battery manufacturers measure such slopes and set a so-called “charge/discharge window” in an appropriate manner in accordance with their products. This is typically referred to as a “rated voltage range” by those in the industry.

However, as the conventional trial and error methods may not be optimal due to variations therein, the inventors of this disclosure have explored some basic principles for establishing a more appropriate or accurate charge/discharge voltage range, based on the following.

Referring to FIG. 5, when batteries are charged (or discharged), a constant current (CC) control method and/or a constant voltage (CV) control method is applied. Under CV control, because the voltage is held constant, even if the state-of-charge (SoC) is high, a certain voltage cannot be exceeded, and the current amount decreases thereof. Namely, it can be said that this is a safe control method near the fully charged region for the battery. In contrast, if CV control is applied at low SoC, because the potential difference at the anode of the battery is low while the voltage is high, the IR value increases, which can result in a dangerously large increase in current.

Under CC control, because the current amount is held constant, the same number of electric charges migrate per time unit regardless of the SoC. Namely, it can be said that this is a safe control method for the battery in a low SoC situation. In contrast, if there is a lag in the control response with respect to sudden voltage changes as the SoC increases, the safe voltage range may be momentarily exceeded.

As such, many types of batteries use a combination of applying both CC control and CV control to achieve battery charging (and/or discharging) in a safe manner.

With respect to vanadium-based batteries, charging and discharging takes place due to reduction and oxidation (i.e., redox) reactions, whereby the potential difference between the anode and cathode greatly effects how energy is stored and released. Some pertinent redox reactions are provided below:

Negative electrode: V²⁺↔V³⁺+e⁻E⁰=−0.255 V

Positive electrode: VO₂⁺+e⁻+2H⁺↔VO²⁺+H₂O E⁰=+1.004 V

Overall reaction: VO₂⁺+V²⁺+2H⁺↔VO²⁺+V³⁺+H₂O E⁰=+1.259 V

In addition, any changes in the concentration (of the liquid electrode) at the anode or cathode results in differences in potentials thereof, and such appears as an open-circuit voltage (OCV) of the battery cell (I=0).

The so-called “state-of charge (SoC)” indicates how much the density of an electrolyte having an oxidation state of +3 and the density of an electrolyte having an oxidation state of +4 changes in theory, respectively, from 100% to 0%.

The equilibrium cell potentials, Eeq for each reaction, are calculated using Nernst's equations (that show the relationship between ion density and voltage) according to the following:

$${E}_{eq , neg} = {E}_{neg}^{0} + \frac{RT}{F} ln ( \frac{{C}_{{V}^{3 +}}}{{C}_{{V}^{2 +}}} )$$

$${E}_{eq , pos} = {E}_{pos}^{0} + \frac{RT}{F} ln ( \frac{{{C}_{{VO}_{2}^{+}} ( {c}_{{H}^{+}} )}^{2}}{{C}_{{VO}_{2}^{+}}} )$$

$${E}_{eq , overall} = {E}_{overall}^{0} + \frac{RT}{F} ln ( \frac{{{C}_{{VO}_{2}^{+}} ( {C}_{{H}^{+}} )}^{2}}{{C}_{{VO}_{2}^{+}}} \frac{{C}_{{V}^{2 +}}}{{C}_{{V}^{3 +}}} )$$

The voltage being measured externally from the battery cell is affected by the current that is applied during charging and/or discharging of the battery cell.

Current multiplied by resistance indicates voltage (i.e., V=IR) and the rise or fall in such voltage is typically indicated as an ohmic loss.

However, the actual operating voltage of VRFB differs from this thermodynamic value. Charging voltage may be larger than 1.2V since the amount of overpotential is required in addition to the thermodynamic voltage.

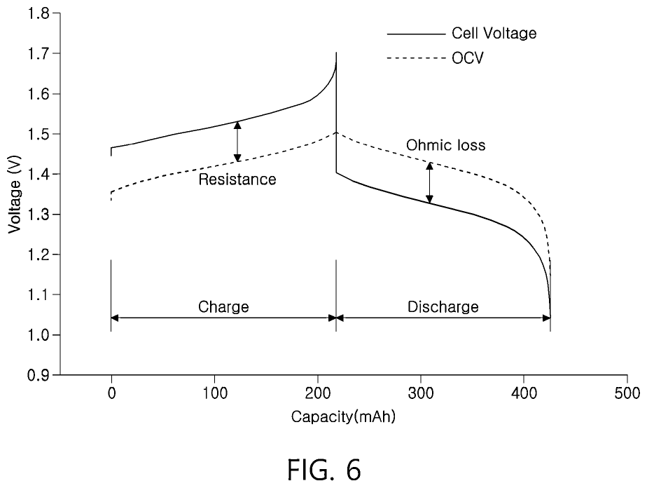

In reference to FIG. 6, the Equations below show the relationship of the voltage and current during charging and discharging at the two electrodes of VFRB, assuming that the overall kinetics are determined by the charge transfer in the electrochemical reaction.

E_{charge}=E_{cell}⁰+η_{d}+η_{c}+iRₜₒₜₐₗ

E_{discharge}=E_{cell}⁰−η_{d}−η_{c}−iRₜₒₜₐₗ
where η_{d} is anodic overpotential and η_{c} cathodic overpotential.

As shown in the above equations, some anodic/cathodic overpotential exists due to some electric current, but unlike lithium-ion batteries (LIBs) and lead batteries, in vanadium-ion batteries (VIBs) such overpotential can be ignored (i.e., is negligible) because there are no phase changes (e.g., from liquid to solid, or from solid to liquid) with respect to the ions in the VIBs.

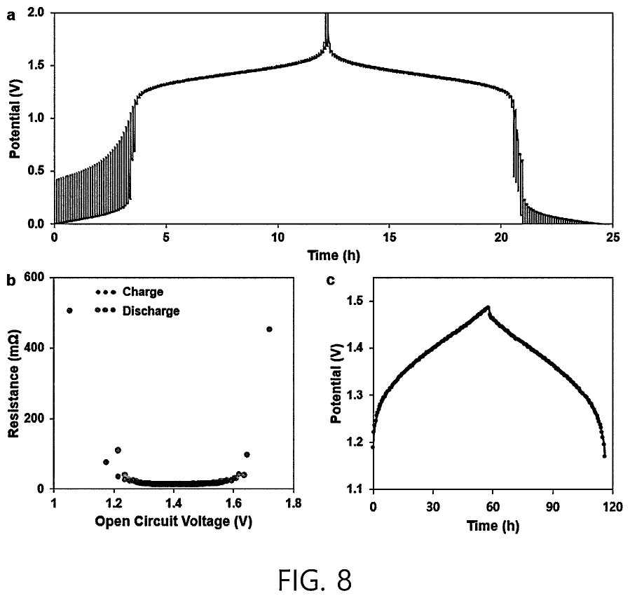

In the graph of FIG. 8, the region showing a drastic change indicates that the battery is damaged, or its efficiency is decreased, which corresponds to a region where charging at high SoC is performed or discharging at low SoC is performed. Namely, it can be said that an important aspect of battery control relates to how the voltage conditions at the end of charging should be set and how the voltage conditions at the end of discharging should be set.

Hereafter, a method of performing a voltage range measurement test according to at least some embodiments will be described.

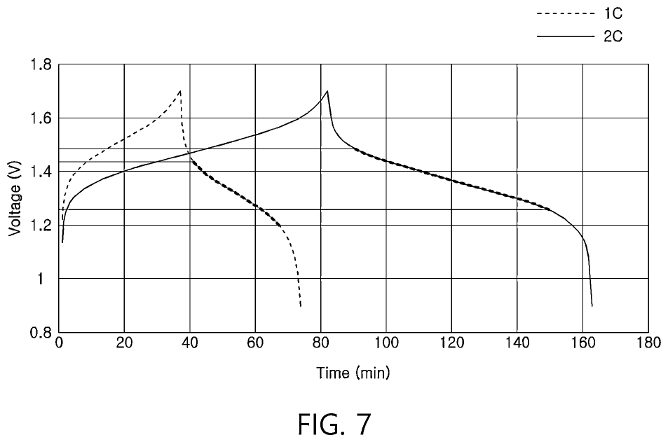

FIG. 7 shows some graphs for different data sets with data regarding the charging and discharging of a battery at constant current. These graphs are not related to VIBs, but merely provided for the purpose of technical background understanding.

For each of the three graphs, the corresponding slope thereof drastically changes at certain points, namely, at or near the start of charging, at or near the end of charging, at or near the start of discharging, and at or near the end of discharging. The linear region indicated as the dotted portions is conventionally used as the typical voltage range for battery control, in consideration of various factors, such as case of control, safe operation conditions, battery lifecycle, and the like.

Here, with respect to how and where the end points of the typical voltage range should be set, many different factors could be used. For example, each end point could be determined to be where the linearity of the data points tend to stop. Alternatively, changes in slope can be measured for a plurality of data points and a particular threshold slope can be set or used to determine where the end points are. As another alternative, it may be found that conducting trial and error measurements result in more effective setting of the end points. As still another method, it may be found that battery testing and operation experience should dictate as to how the end point should be optimized. Due to these fundamental questions and numerous considerations, the inventors of the present disclosure have conceived and devised the following technical approach.

It should be noted that the inventors of the present disclosure focused on vanadium-based batteries (such as VIBs, VRFBs, etc.), but some or all of the concepts and details provided in this disclosure could also be applicable to other types of batteries.

Based upon certain basic electrochemical characteristics of vanadium-based batteries, the following test method for determining a proper voltage range for VIBs is proposed.

FIG. 8 shows some basic electrochemical characteristics of a VIB according to at least some embodiments described herein, wherein (a) depicts a pulsed galvanostatic measurement curve, (b) depicts an internal resistance curve, and (c) depicts a galvanostatic charge/discharge curve.

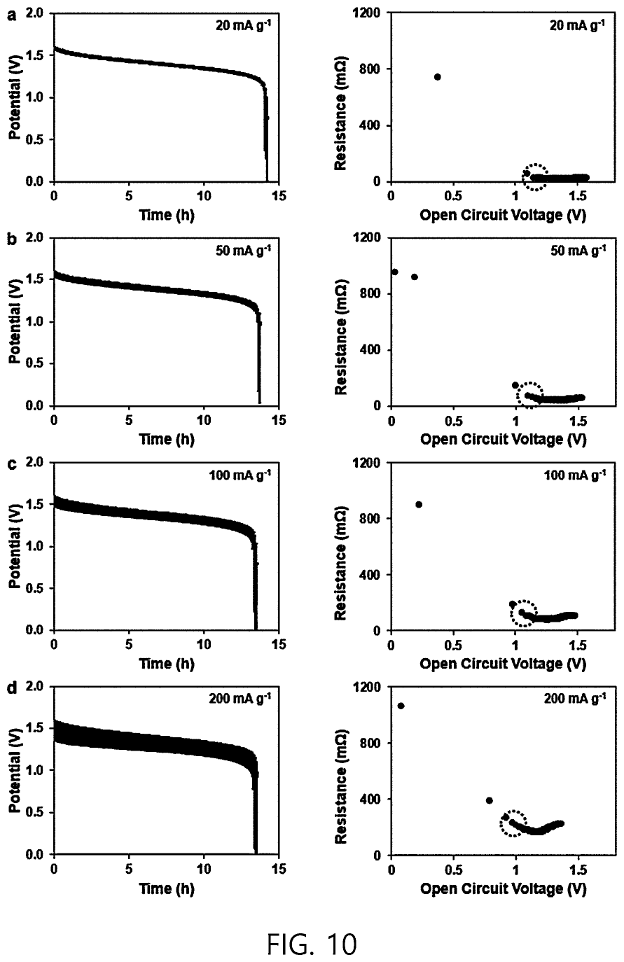

The pulsed galvanostatic measurement was performed to investigate the electrochemical process that is controlled by the kinetic behavior of the vanadium ion reactions between solid and liquid electrodes interface. A pulse current of 10 mA g-1 was repeatedly applied for one minute, followed by five minutes of open circuit relaxation within the voltage range of 0 to 2V, as can be noted in curve (a) in the FIG. 10. It can be noted that the pulsed voltage remains consistently low between about 1.2V and about 1.6V on both the pulse charge and discharge operations, which indicates that the polarization inside the VIB is kept low in the corresponding 1.2V˜1.6V range. However, the pulsed voltage rapidly increased when the potential went beyond the 1.2V˜1.6V range, which indicates that the vanadium reactants in the liquid electrode is consumed, and the polarization increased. Here, the 1.2V˜1.6V range is based upon experimentation by the inventors of the present disclosure, and in some circumstances, voltages of a different range may be employed. Namely, depending upon the electrochemical characteristics of the redox battery and/or the battery application field, such voltage range may be adjusted as needed. For example, the starting voltage may be 1.0V˜1.2V, and the end voltage may slightly exceed 1.6V.

As can be understood from curve (b) in FIG. 8, to observe the kinetic behavior clearly, the internal resistance of the VIB was calculated from the pulsed galvanostatic charge/discharge data, by dividing the pulsed voltage with current, as can be understood from curve (b) in the Figure above. It was observed that internal resistance kept uniform within the 1.2V˜1.6V range with nominal resistance of about 20 mΩ, which indicates that fresh vanadium reactant was immediately supplied on the carbon reaction site. It can be assumed that the carbon electrode repels reacted products allowing fresh reactants to approach and this seems to be a driving force of microfluidic motion inside the VIB. Internal resistance rapidly increased when the potential went beyond the 1.2V˜1.6V range because vanadium reactant was consumed. Therefore, there will be energy loss when the VIB is operated outside the open circuit voltage (OCV) range of 1.2V˜1.6V.

The basic procedure, which is used for establishing a desired voltage range for performing battery control, formulated by the inventors of the present disclosure could be considered as being rather simple. Namely, according to such procedure, charging and/or discharging is performed by using a constant current, but (i) certain time periods are set (or established) in a periodic or other type of manner to obtain particular time regions, and then, (ii) for a plurality of time regions, the current therefor is initialized (i.e., made to equal zero) and (iii) an IR drop is measured thereof, respectively. In other words, an appropriate voltage range (e.g., used for VIB control) can be established based upon a plurality of equivalent internal resistance values being measured with respect to a plurality of open-circuit voltage (OCV) values, which corresponds to the state-of-charge (SoC) values or region related thereto.

Here, it should be noted that a VIB contains an appropriate electrolyte, which can be referred to as a liquid electrode at the anode (or positive electrode) side and at the cathode (or negative electrode) side in the VIB. If there is a change in the amount or degree of electrical charging in such electrolyte, namely, if the average oxidation state (or number) of the ions therein changes, the amount or degree of changes in the resistance within the VIB should be measured (with respect to OCV) in order to perform the desired battery control thereof. In theory, because the OCV and the SoC can be made to match each other in a one-to-one ratio, measuring the OCV can result in obtaining the desired VIB internal resistance values.

In the basic procedure, for the time period or regions, a length or interval thereof can be set accordingly, as long as the frequency is not too quick. For example, an interval of about 10 to 20 Hz may be too narrow (or rapid) for proper measurements to be made. Namely, the time period, region or interval should be made long enough such that current initialization and IR drop measurements can be performed to allow OCV checking to be done as accurately as possible. In a best mode of at least one embodiment, a minimum interval of about 0.1 seconds can be employed to ensure that the desired current initializations and needed measurements are carried out properly.

It can be said that if the time intervals are relatively narrow, the data points on the resistance versus OCV curve will be of higher density, which could lead to results that have a relatively higher degree of precision. Greater precision would require more processing power and time. Thus, there will be a trade-off among these and other competing factors. For example, some procedures for current initialization may be burdensome, but if high precision battery control voltage range is needed and important, the time periods can be set as needed and the measurements and calculations for current initialization and the like can be performed. In contrast, if higher priority is given to the overall stability in system management, the number of times that current initialization, etc. are performed is minimized in order to find the desired battery control voltage range.

In the basic procedure, measuring the IR drops can be achieved by various methods. Here, the IR drops could be measured for all time periods or may be measured for only certain time periods. For example, the inflection points in the resistance versus OCV curve are of particular interest, thus only the IR drops at or near such points could be measured. In contrast, if more IR drop readings are needed, such can be performed accordingly.

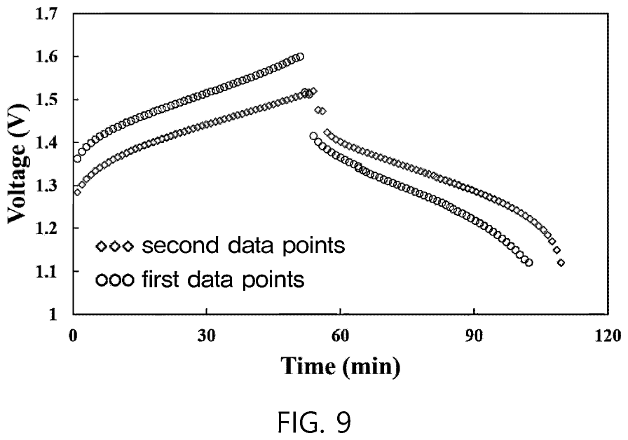

For example, with reference to FIG. 9, the first data points (shown in circular shapes) are for the situation where battery cell resistance is large, and thus there are higher magnitude IR drops at or near the inflection points during charging or discharging. In contrast, the second data points (shown in rectangular shapes) are for the situation of a battery having better performance characteristics, whereby the IR drops are of lower magnitude. In this way, the battery performance can be determined in a comparative manner.

It can be said that there is a trade-off relationship between how many IR drop measurements need to be made in view of any burdensome time and processing involved therewith. For example, referring back to FIG. 9 that shows IR drops measured every minute during the testing procedure, it could be decided that the IR drop measurements near the beginning and near the end of the testing procedure need not be taken per minute, but it may be, for example, sufficient to take measurements every 3 minutes. In contrast, at or near the inflection point, additional detailed measurements (such as every minute, every 30 seconds, every 5 seconds, etc.) could be more meaningful in determining the precise values at which the IR drops change drastically. The specific VIB or particular battery characteristics (such as battery capacity, overall size, type of commercial application, operational environment, performing daytime vs. night-time charging or discharging, manufacturing costs, operation costs, etc.) can affect how such trade-offs can be made.

Hereafter, the basic procedure used for establishing a desired voltage range for performing battery control will be explained in more detail.

When performing battery control, the inventors of the present disclosure recognized that by properly establishing a specific voltage range for an operational region that exhibits relatively low internal resistance in the battery, the ohmic loss thereof can be effectively lowered or minimized. Also, the inventors of the present disclosure recognized that such voltage range can even be adjusted accordingly based upon any changes in the amount of current detected during charging and/or discharging of the battery.

In the conventional art, making adjustments to the voltage range in consideration of changes in the amount of current had not been considered. As such, through carefully conducted research and development activities, the inventors of the present disclosure reached the conclusion that not making appropriate adjustments for such voltage range was one cause of reduced efficiency in the battery charging and/or discharging operations according to the conventional art. Namely, the inventors of the present disclosure recognized that battery charging/discharging efficiency decreased when current above a certain level was applied to the battery using conventional art techniques. Based upon such specific problem recognition, the inventors of the present disclosure have thus devised an effective solution thereto in accordance with the embodiments described herein.

In FIG. 10, some exemplary graphs for experimental results that depict the determination of termination discharge voltage at high current density using pulsed galvanostatic measurement curves and internal resistance curves (for (a) 20 mA g⁻¹, (b) 50 mA g⁻¹, (c) 100 mA g⁻¹, and (d) 200 mA g⁻¹) are shown.

As a result, an optimal voltage range can be established by using the scheme developed by the inventors of the present disclosure, and thus, battery charging and/or discharging operations are drastically improved when compared to the conventional art charging and/or discharging methods.

Due to external or environmental factors as well as variations in internal battery electrochemical characteristics, all types of batteries can be in many types of states according to various operational conditions. Also, there are a limited number of values or variables related to battery characteristics that can be measured without breaking or damaging the battery. For example, representative values that can be measured include voltage, current and resistance, and impedance related to frequencies can be measured as well. In case of lithium-based batteries and some types of lead-based batteries, impedance measurements are used in evaluating battery lifespan and capacity.

For vanadium-based batteries, such as vanadium ion batteries (VIBs), measurements of direct current (DC) and voltage thereof are generally used, because such provide equivalent results when compared to those obtained via impedance measurements. It should be noted that in VIBs, the liquid electrode employed therein may cause certain affects in measuring impedance, and thus using DC-based measurements were found to be more reliable. The mutual relationships or correlations between certain measured values (e.g., current, voltage, resistance) can be changed drastically or show great variations due to temperature and other factors. In addition, the ion distribution (and other electrochemical characteristics) of the liquid electrode in the VIB may cause changes and variations in the average voltage thereof, which may be difficult to detect using external measurement equipment.

Accordingly, the inventors of the present disclosure recognized a necessity or demand to “standardize” (i.e., normalize, systemize, regulate, unify, harmonize, etc.) the states or conditions (or specifications) for a VIB in consideration of certain specific factors, such as temperature, ion distribution, and the like. As a result, the inventors of the present disclosure then identified and decided that such standardized states or conditions can be employed in conducting more precise voltage measurements, which are then employed for improving battery charging and/or discharging operations for the VIB.

Hereafter, some additional technical background matters shall be explained to better understand the concepts and details of the embodiments conceived by the inventors of the present disclosure.

The inventors of the present disclosure were able to identify and/or recognize some interesting effects and/or results upon performing certain types of testing and experiments on VIBs.

With reference to the CC-CV curve, as the battery charging amount (that corresponds to CV control) increases, it was observed that the OCV (for the same SoC value) was relatively low. Namely, if the battery charging/discharging amount is low or if the battery charging/discharging time increases (i.e., becomes lengthy), the OCV decreases.

According to the conventional art theory, it was thought that the OCV cannot change in accordance with current amount, because OCV is a value that is measured when current equals zero.

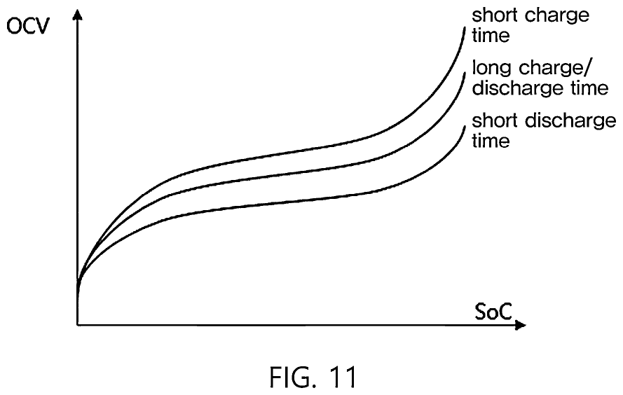

FIG. 11 depicts the SoC versus OCV relationships for three different cases as per the three graphs shown from top to bottom, i.e., for short charging time, for long charging/discharging time, and for short discharging time.

Based on such observations, the inventors of the present disclosure came to the conclusion that there must be some element having transient characteristics during actual charging and/or discharging of the VIB, and this would mean that there must be some particular method or condition(s) needed for such element to achieve saturation.

As such, the inventors of the present disclosure believe that the aforementioned observation may be caused by the following.

With reference to a single battery cell in a vanadium-based battery (VIB or VRFB), the battery casing is basically a container that is divided in half by a membrane, resulting in a first half cell (e.g., for the cathode) containing a liquid electrode and a solid electrode along an inner wall thereof, and a second half cell (e.g., for the anode) containing a liquid electrode and a solid electrode along an inner wall thereof. In such structure, so-called battery reactions mostly take place on or near the carbon fiber surface of each solid electrode. The reasons for this will be explained in more detail hereafter.

The liquid electrode is highly acidic, and thus a large number of protons exist therein. Such protons can move and pass through the membrane to achieve electrical balancing in the liquid electrode. Also, during charging and discharging, the ion distribution near the carbon fiber surfaces (at each solid electrode) is different from the ion distribution at other regions in the liquid electrode that are further away from the carbon fiber surfaces (of each solid electrode). As a result, the oxidation states (or oxidation numbers) of the vanadium ions in the liquid electrode are different depending upon how near or far such vanadium ions are from the carbon fiber surfaces (of each solid electrode).

For example, it was observed that vanadium ions near the solid cathode have oxidation states close to +2, while vanadium ions further away from the solid cathode have oxidation states approaching +3. Also, it was observed that vanadium ions near the solid anode have oxidation states close to +5, while vanadium ions further away from the solid anode have oxidation states approaching +4.

Due to the electrical current(s) during charging and/or discharging, electrochemical (and/or electro-conductive) battery reactions first take place within the liquid electrode regions adjacent to the carbon fiber surfaces of each solid electrode (i.e., in the near-fiber regions). Thereafter, due to electric field effects caused by ion diffusion and/or electrical imbalances, additional ions move or travel upon spreading or diffusion.

When CC (constant current) control is applied to the battery, the solid electrode of the VIB described above is electrically connected with respect to the constant current (whereby the potential is the same), and thus, measuring the OCV of the battery results in the potential corresponding to the surface concentration at the solid electrode being measured. Namely, external measurement of the OCV for the VIB actually corresponds to the potential that exists in the near-fiber region (i.e., at or near the carbon fiber surface of the solid electrode). However, because establishing an optimal voltage range to be used for battery control during charging and/or discharging requires the determination of an ‘average SoC’ with respect to the overall battery operation and also requires certain relationships between various OCV-SoC values to be measured, calculated or deduced, such simple external measurements of OCV values lacks accuracy with respect to a VIB. Namely, because the overall battery capacity of the VIB is obtained by multiplying the ‘average SoC’ with the volume of the liquid electrode in the VIB, a simple external measurement of OCV values without consideration of other factors and without applying any other conditions would not lead to the desired results.

In essence, because the VIB employs a liquid electrode, the technical considerations and requirements involved in performing battery charging and/or discharging operations for vanadium-based batteries compared with the technical considerations and requirements for non-vanadium-based batteries (e.g., lithium-based batteries, lead-based batteries, etc.) are completely different. As such, the inventors of the present disclosure further recognized that some additional factors also need to be considered in order to establish an optimal voltage range to be used for battery control during charging and/or discharging of VIBs and the like.

In this regard, the state of a battery is greatly affected by environmental temperature. As such, the proper evaluation of a battery will require that the environmental temperature be maintained at a relatively constant level. For example, the following matters should be noted:

Understanding the effects of environmental temperature on efficiency is important for ESS operation.

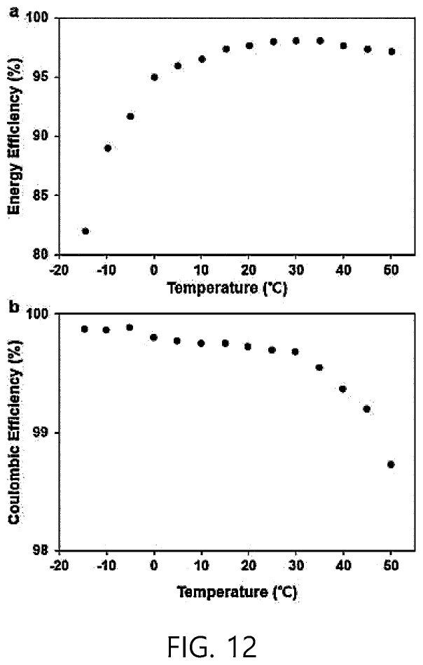

Energy efficiency of the VIB at various environmental temperatures was investigated, as per FIG. 12, which depicts the effects of environmental temperature on VIB performance, whereby (a) shows energy efficiency and (b) shows Coulombic efficiency.

Energy efficiency under 1 C-rate was measured under environmental temperature ranging from −15° C. to 50° C.

Here, the battery discharge rate (C-rate) may be expressed as follows:

C-rate=(a battery output corresponding to an amount of exhaustion during a certain time period)

Namely, 1C can be viewed as the battery output when exhausted in 1 hour.

It was found that about 25° C. to 35° C. was a favorable temperature range resulting in highest energy efficiency of about 98.1%. Energy efficiency slightly decreased when over 40° C. because of decreased Coulombic efficiency. The mixing of cathode and anode liquid electrodes through the separator (membrane) is accelerated at elevated temperature because the VIB has liquid electrode resulting in decreased Coulombic efficiency. Nevertheless, energy efficiency remained at about 97.3% even at 50° C.

The decrease of energy efficiency was more severe at lower temperatures. At relatively low temperature, the liquid electrode becomes more viscous, leading to slower chemical reactions, slower charge transfer rates, and lower vanadium ion diffusivity. The decrease in energy efficiency from about 25° C. to 0° ° C. was gradual, where energy efficiency at 0° C. still maintained 94.9%. However, energy efficiency decrease slope inflected and became severe under 0° C. and energy efficiency fell to 84.3% at −15° C. Heating the battery consumes energy at the ESS, resulting in lower energy efficiency of the entire ESS. But, when the battery is heated, battery energy efficiency rises resulting in higher energy efficiency of the ESS. Therefore, understanding the relationship between battery performance and operation temperature is crucial for efficient ESS operation.

In view of the above-described technical issues and in consideration of how a battery should be evaluated (based upon its charging and/or discharging performance), the inventors of the present disclosure contemplated about how certain affects (caused by different current amounts) could be removed or suppressed, as well as how the affects due to environmental temperature should be dealt with.

As a result, the inventors of the present disclosure have proposed some specific ‘standard conditions’ under which vanadium-based batteries, such as VIBs, VRFBs, etc., should be evaluated or assessed. Such standardized conditions may also be used for quality control, analyzing abnormal system operations, battery re-use, and for many other types of battery related operations.

The measurements of energy efficiency at 1 discharge rate (C-rate) conditions under an environmental temperature range from −15° C. to 50° C. can be considered as optimal discharge rate (C-rate) conditions obtained by the present inventors through research, development and various experiments. However, the present inventors confirmed that using 0.5 C-rate or above conditions or conditions using a range of 0.5˜1.5 C-rate also led to results that fall within the characteristics of the embodiments of present disclosure. Because unsatisfactory experimentation results may be obtained when the C-rate value or range exceeds the above findings, the present inventors suggest the use of the particular C-rate value and range stated above for at least some of the embodiments explained herein.

Regarding the standard conditions, the battery evaluation should be: (1) performed at a constant or uniform temperature, (2) performed at a particular voltage range or region, and (3) performed upon waiting until an equilibrium state is achieved.

In addition, the estimation of state-of-charge (SoC) values also should be performed under the standard conditions explained above. The external measurements that can be made for a battery are affected by environmental temperature and affected by the instantaneous current amount with respect to the battery, and thus, effective removal or suppression of such factors will lead to more accurate SoC measurements.

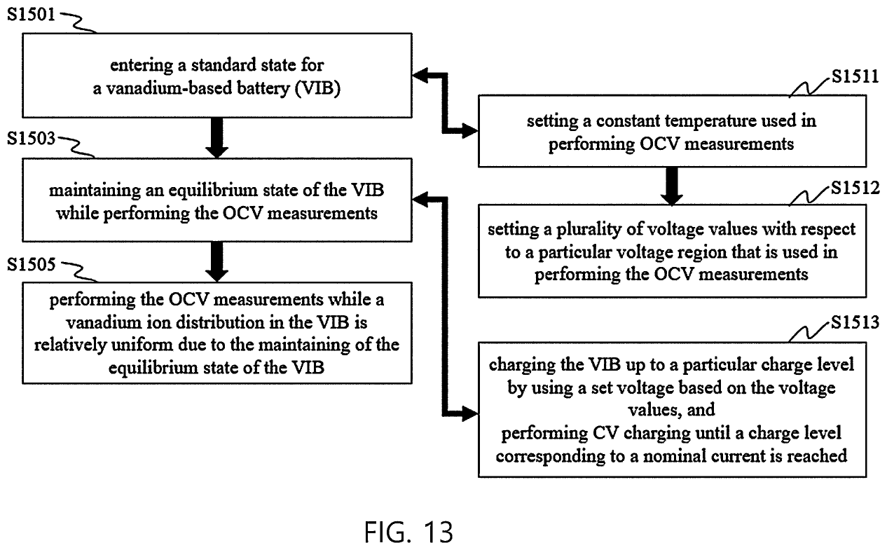

FIG. 13 shows an exemplary flow chart of the procedures for entering a standard state for a vanadium-based battery according to at least some embodiments described herein.

In step S1501, a standard state for a vanadium-based battery is entered.

In step S1503, the OCV is measured as depicted, and more particularly, at least one among the voltage decrease (IR drop) and the voltage increase (IR rise) can be measured (S1513). During such measurements, the standard state of the vanadium-based battery is maintained (S1512).

In more detail, in step S1511 after the previous step S1501, a constant temperature used for the OCV measurements is set.

Also, a plurality of voltage values are set with respect to the particular voltage range used for the OCV measurements (S1511), and as shown in step S1512, the standard state of the vanadium-based battery is continued during the OCV measurements.

Through these procedures, at least one resistance value can be obtained for the vanadium-based battery (S1505), such are compared with normal resistance values (S1507), and based upon the differences between the obtained resistance values and the normal resistance values, a state of the vanadium-based battery can be deduced.

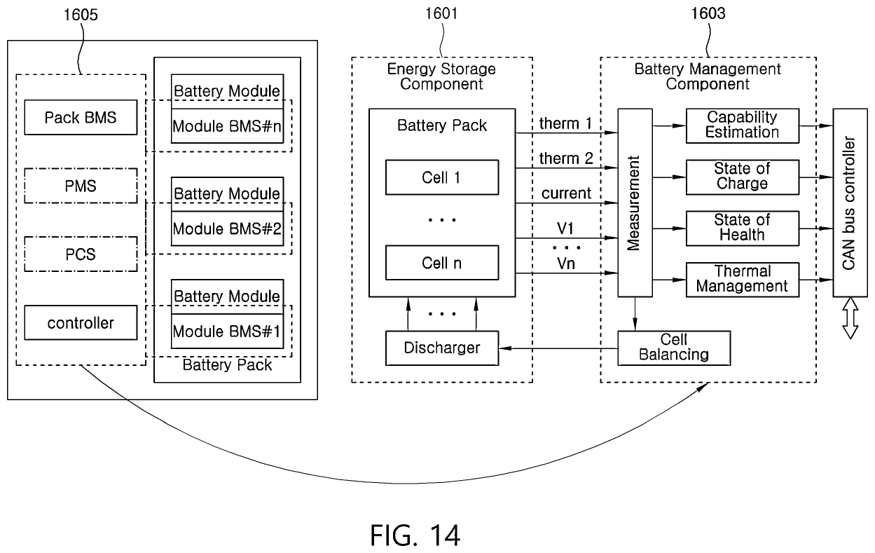

FIG. 14 shows an exemplary apparatus that can perform the steps of FIG. 13 according to at least some embodiments described herein. Depicted is an energy storage device (100) that can be connected with an electric power grid which can be divided into one or more so-called primary power regions and one or more so-called supportive power regions.

The energy storage device (100) can have an energy storage module (110) that includes a battery pack comprised of a plurality of battery modules and a module BMS (battery management system) that handles battery management functions for each battery module.

The controller (150) can determine whether to charge or discharge the energy storage module (110) by using the power amount measurements results for the primary and supportive power regions. Also, the controller (150) can determine whether to discharge at least one among the primary power region and one or more chargers located at the supportive power region.

The energy storage device (100) can include a Pack BMS (120) that manages the charging ang discharging of the energy storage module (110). Also, the energy storage device (100) can selectively include a PMS (Power Management System) (120) and a PCS (Power Conversion System) (140). When the energy storage device (100) has both the PMS (130) and the PCS (140), such can be called a combined ESS.

Additionally, depending upon how the energy storage device (100) is installed or implemented, the PMS (130) and the PCS (140) can be physically separate devices from the energy storage device (100). The PMS (130) and the PCS (140) can thus be independently operated and through various means of communication, data can be exchanged with the energy storage device (100) to provide operationally control thereto.

The batteries in each battery module of the energy storage device (100) can be charged with power or electricity via the PCS (140), which can receive electricity supply for storage in the batteries or can release electricity through power lines or systems. Here, the PCS (140) can perform AC/DC conversions or can convert the voltages or frequencies that are sent or received.

The PMS (130) exchanges information via communication with the PCS (140) to provide the PCS (140) with information needed to control the charging or discharging of the batteries.

The Module BMS can manage a corresponding battery by monitoring their charged state, discharged state, temperature, voltage, current, and the like. The Pack BMS (120) is a battery management system with respect to the entire battery pack.

The controller (150) and the PMS (130) can be combined together or integrated and operate as a single entity. Alternatively, the controller (150) can be an independent device.

In some embodiments, the controller (150) can be implemented within the PMS (130), Still alternatively, the PMS (130) can be implemented with some or all of the functionality of the controller (150).

With respect to the procedures for performing an assessment of a vanadium-based battery as per FIG. 13, the energy storage device (100) may have therein a setting element configured to set a plurality of standard conditions related to a vanadium-based battery to be used in a method of performing an assessment of the vanadium-based battery; and a measurement element configured to perform one or more measurements with respect to the vanadium-based battery in accordance with the set standard conditions, wherein the standard conditions include a constant temperature, a plurality of voltage values with respect to a particular voltage range, and an equilibrium state of the vanadium-based battery. For example, at least one among the setting element and the measurement element can be implemented in the controller (150), in the PMS (130) or in the Module BMS. Also, for example, the setting element and the measurement element can be implemented in hardware, software or a combination thereof.

Meanwhile, the portion (1605) indicated by the dotted lines handles battery management control and can be considered as a battery management component (1603) of the energy storage system (ESS).

Such battery management component (1603) is operatively connected with the energy storage component (1601), which is comprised of one or more battery packs having multiple battery cells (cell 1, cell 2, . . . , cell n) and is also connected with a discharger.

The battery management component (1603) has a measurement unit that performs measurements with respect to various values (temperature 1, temperature 2, current, V1, Vn, etc.). Connected with the measurement unit are a capability measurement unit, a charging state unit, a heath state unit, a thermal management unit, etc. that respectively perform certain functions. Additionally, there may be a cell balancing unit that performs cell balancing for the battery packs according to the measurement results from the measurement unit. Finally, there may be a connection control unit, such as a CAN bus controller, that manages connections with other elements.

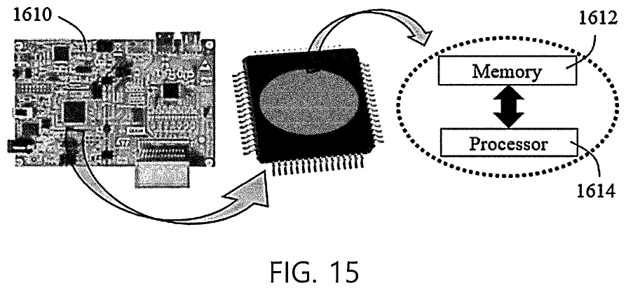

FIG. 15 is a conceptual drawing about an exemplary semiconductor chip assembly according to at least embodiment.

The hardware that handles battery management or control may be implemented on a printed circuit board (PCB: 1610) or the like that includes a semiconductor chip assembly or structure, whereby the semiconductor chip, the semiconductor chip assembly or the semiconductor chip structure includes a memory (1612) or a similar storage means and a processor (1614) or similar controller. The software and/or firmware needed for such hardware for battery management and control are also implemented in order to perform the various methods and features described with respect to the exemplary embodiments herein.

The characteristics of the embodiments of present disclosure can also be described as follows.

The present disclosure provides a semiconductor chip assembly comprising: a memory containing information related to entering a standard state for a vanadium-based battery; and a processor operatively connected with the memory, and configured to provide instructions or commands for entering of the standard state for the vanadium-based battery, the standard state entered by setting a constant temperature that is used in performing open circuit voltage (OCV) measurements, and by setting one or more voltage values with respect to a particular voltage region that is used in performing the OCV measurements, the processor is further configured to provide instructions or commands for maintaining an equilibrium state of the vanadium-based battery while performing the OCV measurements.

The constant temperature is set to be within a range of 23° C., with a plus or minus deviation of two degrees, and the one or more voltage values are set such that a charging start voltage is about 1.0˜1.2V and such that at least one additional voltage value is greater than the charging start voltage and within the particular voltage region.

The equilibrium state of the vanadium-based battery is maintained by: charging the vanadium-based battery up to a particular charge level by using a set voltage based on the one or more voltage values, and performing constant voltage (CV) charging until a charge level corresponding to a nominal current is reached.

The processor further provides instructions or commands for performing the OCV measurements after the CV charging has begun.

The particular charge level is approximately 0.5 C-rate or greater and the nominal current is approximately 0.01 C-rate.

The OCV measurements are performed while a vanadium ion distribution in the vanadium-based battery is relatively uniform due to the maintaining of the equilibrium state of the vanadium-based battery.

The processor further provides instructions or commands for operating the vanadium-based battery within a OCV range of 1.2V to 1.6V.

Also, the present disclosure provides a method for a semiconductor assembly, the method comprising: entering a standard state for a vanadium-based battery by setting a constant temperature that is used in performing open circuit voltage (OCV) measurements, and by setting a plurality of voltage values with respect to a particular voltage region that is used in performing the OCV measurements; and maintaining an equilibrium state of the vanadium-based battery while performing the OCV measurements.

The constant temperature is set to be within a range of 23° C., with a plus or minus deviation of two degrees, and the one or more voltage values are set such that a charging start voltage is about 1.0˜1.2V and such that at least one additional voltage value is greater than the charging start voltage and within the particular voltage region.

The equilibrium state of the VIB is maintained by: charging the vanadium-based battery up to a particular charge level by using a set voltage based on the one or more voltage values, and performing constant voltage (CV) charging until a charge level corresponding to a nominal current is reached.

The method further comprises: performing the OCV measurements after the CV charging has begun.

The particular charge level is approximately 0.5 C-rate or greater and the nominal current is approximately 0.01 C-rate.

The OCV measurements are performed while a vanadium ion distribution in the vanadium-based battery is relatively uniform due to the maintaining of the equilibrium state of the vanadium-based battery.

The method further comprises: operating the vanadium-based battery within a OCV range of 1.2V to 1.6V.

Additionally, the present disclosure provides a system having a semiconductor assembly, the system comprising: at least one energy storage component having a plurality of vanadium-based batteries arranged in cells or packs; and a battery management component, operatively connected with the energy storage component, and configured to provide battery management control for entering a standard state for the energy storage component, the standard sate entered by setting a constant temperature that is used in performing open circuit voltage (OCV) measurements for the vanadium-based batteries arranged in cells or packs, by setting a plurality of voltage values with respect to a particular voltage region that is used in performing the OCV measurements for the vanadium-based batteries arranged in cells or packs, and the battery management component is further configured to provide battery management control for maintaining an equilibrium state of the energy storage component or at least one of the vanadium-based batteries therein while performing the OCV measurements.

The battery management component, for performing the OCV measurements, provides battery management control for: the constant temperature is set to be within a range of 23° ° C., with a plus or minus deviation of two degrees, and the one or more voltage values are set such that a charging start voltage is about 1.0˜1.2V and such that at least one additional voltage value is greater than the charging start voltage and within the particular voltage region.

The equilibrium state of the vanadium-based battery is maintained by: charging at least one of the vanadium-based batteries up to a particular charge level by using a set voltage based on the one or more voltage values, and performing constant voltage (CV) charging until a charge level corresponding to a nominal current is reached.

The battery management component provides battery management control for performing the OCV measurements after the CV charging has begun, and wherein the particular charge level is approximately 0.5 C-rate and the nominal current is approximately 0.01 C-rate.

The OCV measurements are performed while a vanadium ion distribution in the at least one of the vanadium-based batteries is relatively uniform due to the maintaining of the equilibrium state of the energy storage component or the at least one of the vanadium-based batteries.

The battery management component further provides battery management control for operating the energy storage component or the at least one of the vanadium-based batteries therein, within a OCV range of 1.2V to 1.6V.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words used in the present disclosure appearing in the singular or plural concepts may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit essence of the disclosure. For example, while blocks are presented in a given arrangement, alternative embodiments may perform similar functionalities with different components and/or circuit topologies and/or procedures, and some blocks may be deleted, moved, added, subdivided, combined, and/or modified. Each of these blocks may be implemented in a variety of different ways. Any suitable combination of the elements and acts of the various embodiments described above can be combined to provide further embodiments. The various features and processes described above may be implemented independently of one another, or may be combined in various ways. All possible combinations and sub-combinations of features of this disclosure are intended to fall within the scope of this disclosure.

It should be understood that the subject matter defined in the appended claims is not necessarily limited to the specific implementations described above. The specific implementations described above are disclosed as examples only.

What is claimed is:

1. A semiconductor chip assembly comprising:
a memory containing information related to entering a standard state for a vanadium-based battery; and
a processor operatively connected with the memory, and configured to provide instructions or commands for entering of the standard state for the vanadium-based battery, the standard state entered by setting a constant temperature that is used in performing open circuit voltage (OCV) measurements, and by setting one or more voltage values with respect to a particular voltage region that is used in performing the OCV measurements,
wherein the processor is further configured to provide instructions or commands for maintaining an equilibrium state of the vanadium-based battery while performing the OCV measurements.

2. The assembly of claim 1,
wherein the constant temperature is set to be within a range of 23° ° C., with a plus or minus deviation of two degrees, and
wherein the one or more voltage values are set such that a charging start voltage is about 1.0˜1.2V and such that at least one additional voltage value is greater than the charging start voltage and within the particular voltage region.

3. The assembly of claim 2, wherein the equilibrium state of the vanadium-based battery is maintained by:
charging the vanadium-based battery up to a particular charge level by using a set voltage based on the one or more voltage values, and
performing constant voltage (CV) charging until a charge level corresponding to a nominal current is reached.

4. The assembly of claim 3, wherein the processor further provides instructions or commands for performing the OCV measurements after the CV charging has begun.

5. The assembly of claim 4, wherein the particular charge level is approximately 0.5 C-rate or greater and the nominal current is approximately 0.01 C-rate.

6. The assembly of claim 4, wherein the OCV measurements are performed while a vanadium ion distribution in the vanadium-based battery is relatively uniform due to the maintaining of the equilibrium state of the vanadium-based battery.

7. The assembly of claim 1, wherein the processor further provides instructions or commands for operating the vanadium-based battery within an OCV range of 1.2V to 1.6V.

8. A method for a semiconductor assembly, the method comprising:
entering a standard state for a vanadium-based battery by setting a constant temperature that is used in performing open circuit voltage (OCV) measurements, and by setting a plurality of voltage values with respect to a particular voltage region that is used in performing the OCV measurements; and
maintaining an equilibrium state of the vanadium-based battery while performing the OCV measurements.

9. The method of claim 8,
wherein the constant temperature is set to be within a range of 23° ° C., with a plus or minus deviation of two degrees, and
wherein the one or more voltage values are set such that a charging start voltage is about 1.0˜1.2V and such that at least one additional voltage value is greater than the charging start voltage and within the particular voltage region.

10. The method of claim 9, wherein the equilibrium state of the vanadium-based battery is maintained by:
charging the vanadium-based battery up to a particular charge level by using a set voltage based on the one or more voltage values, and
performing constant voltage (CV) charging until a charge level corresponding to a nominal current is reached.

11. The method of claim 10, further comprising: performing the OCV measurements after the CV charging has begun.

12. The method of claim 11, wherein the particular charge level is approximately 0.5 C-rate or greater and the nominal current is approximately 0.01 C-rate.

13. The method of claim 11, wherein the OCV measurements are performed while a vanadium ion distribution in the vanadium-based battery is relatively uniform due to the maintaining of the equilibrium state of the vanadium-based battery.

14. The method of claim 8, further comprising: operating the vanadium-based battery within an OCV range of 1.2V to 1.6V.

15. A system having a semiconductor chip assembly, the system comprising:
at least one energy storage component having a plurality of vanadium-based batteries arranged in cells or packs; and
a battery management component, operatively connected with the energy storage component, and configured to provide battery management control for entering a standard state for the energy storage component,
the standard sate entered by setting a constant temperature that is used in performing open circuit voltage (OCV) measurements for the vanadium-based batteries arranged in cells or packs, and by setting a plurality of voltage values with respect to a particular voltage region that is used in performing the OCV measurements for the vanadium-based batteries arranged in cells or packs,
wherein the battery management component is further configured to provide battery management control for maintaining an equilibrium state of the energy storage component or at least one of the vanadium-based batteries therein while performing the OCV measurements.

16. The system of claim 15, wherein the battery management component, for performing the OCV measurements, provides battery management control for:
wherein the constant temperature is set to be within a range of 23° ° C., with a plus or minus deviation of two degrees, and
wherein the one or more voltage values are set such that a charging start voltage is about 1.0˜1.2V and such that at least one additional voltage value is greater than the charging start voltage and within the particular voltage region.

17. The system of claim 16, wherein the equilibrium state of the vanadium-based battery is maintained by:
charging at least one of the vanadium-based batteries up to a particular charge level by using a set voltage based on the one or more voltage values, and
performing constant voltage (CV) charging until a charge level corresponding to a nominal current is reached.

18. The system of claim 17, wherein the battery management component provides battery management control for performing the OCV measurements after the CV charging has begun, and wherein the particular charge level is approximately 0.5 C-rate and the nominal current is approximately 0.01 C-rate.

19. The system of claim 18, wherein the OCV measurements are performed while a vanadium ion distribution in the at least one of the vanadium-based batteries is relatively uniform due to the maintaining of the equilibrium state of the energy storage component or the at least one of the vanadium-based batteries.

20. The system of claim 15, wherein the battery management component further provides battery management control for operating the energy storage component or the at least one of the vanadium-based batteries therein, within an OCV range of 1.2V to 1.6V.
